(19) United States
(12) Patent Application Publication
(10) Pub. No.: US 2013/0235449 A1
(43) Pub. Date: Sep. 12, 2013

(54) Optical Amplifier and Optical Transmission System

(71) Applicant: FURUKAWA ELECTRIC CO., LTD., Tokyo (JP)

(72) Inventor: Mikiya SUZUKI, Tokyo (JP)

(73) Assignee: Furukawa Electric Co., Ltd., Tokyo (JP)

(21) Appl. No.: 13/872,420

(22) Filed: Apr. 29, 2013

Related U.S. Application Data
(63) Continuation of application No. PCT/JP2010/069324, filed on Oct. 29, 2010.

(51) Int. Cl. H01S 5/06; H01S 3/13; H01S 3/067

(52) U.S. Cl. CPC H01S 5/0612; H01S 3/06754; H01S 3/13
USPC 359/341.1

(57) ABSTRACT

An optical amplifying apparatus that amplifies an optical signal, including an input section whereto the optical signal is inputted, a laser light source that generates laser light, the laser light source including an uncooled semiconductor laser device, an optical fiber that amplifies the optical signal by a stimulated emission based on the laser light from the laser light source, an output section that outputs the optical signal amplified by the optical fiber, and a passive optical component disposed between the optical fiber and the output section. The laser light source is thermally coupled to the optical fiber and/or the passive optical component via a thermally conductive medium. An oscillating wavelength of the laser light source is varied by increasing a temperature of the laser light source with heat generated by the optical fiber and/or the passive optical component.

### CROSS REFERENCE TO RELATED APPLICATIONS

This is a continuation application of International Patent Application No. PCT/JP2010/069324, filed Oct. 29, 2010, the full content of which is hereby incorporated by reference herein in its entirety.

### TECHNICAL FIELD

The present invention relates to an optical amplifying apparatus and an optical transmission system that are applicable in the field of optical communication or the like.

### BACKGROUND ART

Recently, fiber optic communication networks called FTTx (Fiber To The x) such as a fiber optic communication network reaching a user's home are widespread. In such a fiber optic communication network, an optical amplifying apparatus is used for the purpose of compensating for transmission losses in a transmission path and distribution losses in a distributor for that distributes optical signals between a plurality of subscribers.

Such an optical amplifying apparatus may be, for example, a known fiber-type optical amplifying apparatus (EDFA: Erbium Doped Fiber Amplifier) that amplifies an optical signal by inputting an optical signal such as a video signal and also inputting a pump light from an optical pump source into an optical fiber having a core portion doped with erbium, which serves as an optical amplification substance. Further, in recent years, it is known to dope the core portion with ytterbium that enables a high-power laser having a watt-level output as an absorption band to be used as an optical pump source. It is also known to use a double-clad optical fiber in which, in order to increase a pump light intensity that can be coupled in a core portion, an optical signal is propagated in a single mode through a core portion and a pump light from a high-power multimode laser light source is propagated in a multimode through a cladding portion surrounding the core portion (see Japanese Laid-Open Patent Publication No. 2008-53294).

In amplifying a video in an optical amplifying apparatus using the aforementioned optical fiber, an image quality may be degraded by factors including a noise and a signal distortion that occur in the optical amplifying apparatus. One of the indices representing a noise in the optical amplifying apparatus is a noise index (NF: Noise Figure). With a high NF, a snow-like noise appears on a receiver screen, since the noise from the optical amplifying apparatus is superimposed on the video signal. Indices that represent a signal distortion include CSO (Composite Second Order Distortion) and CTB (Composite Triple Beat Distortion), and a picture quality is largely affected by such distortions.

In order to reduce such picture quality degrading factors in analog transmissions, it is desirable to decrease a length of an optical fiber. However, by decreasing a length of an optical fiber, a residual pump light which was not used in a stimulated emission and has remained will occur. FIG. 10 is a diagram showing a relationship between the length of optical fiber and the intensity of residual pump light when excited by a pump light having a center frequency of 933 nm. As shown in FIG. 10, the intensity of residual pump light tends to increase as the length of optical fiber decreases. When such a residual pump light is generated, the optical fiber or the like may be adversely affected by heat and energy originating from the residual pump light.

Accordingly, it is an object of the invention to provide an optical amplifying apparatus that can improve analog characteristics while suppressing an occurrence of a residual pump light.

### SUMMARY

In order to achieve the above object, according to an aspect of the invention, an optical amplifying apparatus that amplifies an optical signal includes an input section whereto the optical signal is inputted, a laser light source that generates laser light, an optical fiber that amplifies and outputs the optical signal by a stimulated emission based on the laser light from the laser light source, an output section that outputs the optical signal amplified by the optical fiber, and a passive optical component disposed between the optical fiber and the output section, the laser light source being thermally coupled to the optical fiber and/or the passive optical component via a thermally conductive medium.

With such a structure, analog characteristics can be improved while suppressing the generation of the residual pump light.

According to the optical amplifying apparatus of the aspect of the invention, in addition to the aforementioned features, the heat generated by the optical fiber and/or the passive optical component is transferred to the laser light source, and a wavelength band of laser light generated by the laser light source when a thermally steady state is reached is set to substantially match a wavelength at which an absorptance of the optical fiber is high.

With such a structure, the conversion efficiency can be improved and analog characteristics can be improved while suppressing the residual pump light.

According to the optical amplifying apparatus of the aspect of the invention, in addition to the aforementioned features, the thermally conductive medium is a heat sink that dissipates heat generated by the optical fiber and/or the passive optical component and thermally couples by disposing the laser light source on the heat sink.

With such a structure, by using a heat sink having a high thermal conductivity as thermally-conductive medium, the thermal coupling between the two is ensured without increasing a number of parts.

The optical amplifying apparatus of the aspect of the invention includes, in addition to the aforementioned features, a temperature detecting section that detects a temperature of the laser light source and thermally coupled to the laser light source, and a temperature adjusting section that adjusts a temperature of a system including the laser light source based on a temperature detection result from the temperature detecting section in such a manner that a wavelength band of laser light generated by the laser light source substantially matches a wavelength band in which an absorptance of the optical fiber is high.

With such a structure, since the temperature of the laser light source can be always kept constant, for example, a residual pump light can be positively suppressed without is influenced by an environmental temperature or the like.

According to the optical amplifying apparatus of the aspect of the invention, in addition to the aforementioned features, a power of a residual pump light outputted from the optical fiber being set at less than or equal to 500 mW.

With such a structure, the residual pump light can be prevented from adversely affecting an optical fiber or the like.

According to another aspect of the invention, an optical transmission system includes an optical transmitting apparatus that transmits an optical signal, the aforementioned optical amplifying apparatus, and an optical receiving apparatus that receives the optical signal amplified by the optical amplifying apparatus.

With such a structure, by improving a communication quality of the transmission system and reducing the power consumption, the cost required for the maintenance of the system can be saved.

According to an optical amplifying apparatus and an optical transmission system of an aspect of the invention, analog characteristics can be improved while reducing the power consumption.

### BRIEF DESCRIPTION OF DRAWINGS

FIG. 1 is a block diagram showing an exemplary configuration of an optical amplifying apparatus of the invention.

FIG. 2 is a diagram showing a cross-sectional structure of an amplification optical fiber shown in FIG. 1 and a refractive index of each portion.

FIG. 3 is a graph showing a profile of wavelength characteristics of the pump light generated by a laser diode.

FIG. 4 is a diagram showing an example of a relationship between an amplification optical fiber and a laser diode arranged in a heat sink.

FIG. 5 is a graph showing a relationship between a ground state absorption and an excited state gain of an amplification optical fiber with respect to a wavelength.

FIG. 6 is a plot showing an amplification optical fiber length and a residual pump light according to the present embodiment and an example of the related art.

FIG. 7 is a diagram showing an exemplary configuration of an optical transmission system in which an optical amplifying apparatus of the present embodiment is employed.

FIG. 8 is a diagram showing another example of a relationship between an amplification optical fiber and a laser diode arranged in a heat sink.

FIG. 9 is a diagram showing still another example of a relationship between an amplification optical fiber and a laser diode arranged in a heat sink.

FIG. 10 is a plot showing an amplification optical fiber length and a residual pump light according to an example of the related art.

### DESCRIPTION OF THE PREFERRED EMBODIMENTS

An embodiment of the present invention will now be described.

(A) Configuration of Embodiment

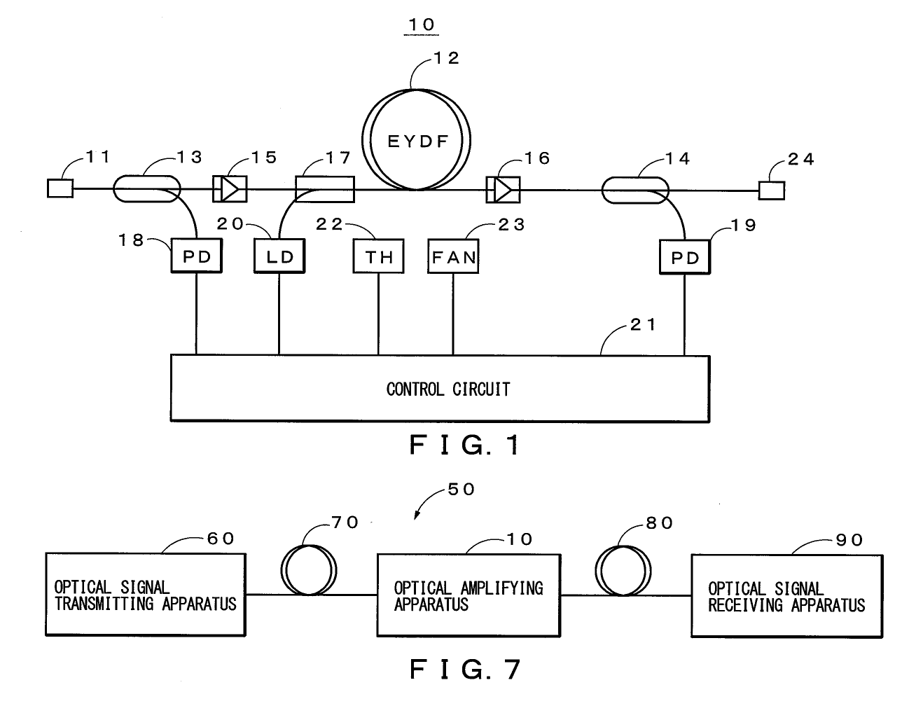

FIG. 1 is a diagram showing an exemplary configuration of an optical amplifying apparatus of an embodiment of the invention. As shown in FIG. 1, an optical amplifying apparatus 10 includes an input port 11, an amplification optical fiber 12, optical couplers 13 and 14, optical isolators 15 and 16, a pump light mixer 17, photodiodes 18 and 19, a laser diode 20, a control circuit 21, a thermistor 22, a cooling section 23 and an output port 24.

The input port 11 is, for example, an optical connector or the like, and for example, an optical signal having a wavelength of 1550 nm obtained by modulating laser light with a AM-VSB (Amplitude Modulation-Vestigial Side-Band) signal having 40 sinusoidal carriers within a frequency range of 91.25-343.25 MHz is inputted thereto. The amplification optical fiber (EYDF: Erbium Ytterbium Doped Fiber) 12 amplifies the optical signal by a stimulated emission caused by a pump light generated by the laser diode 20.

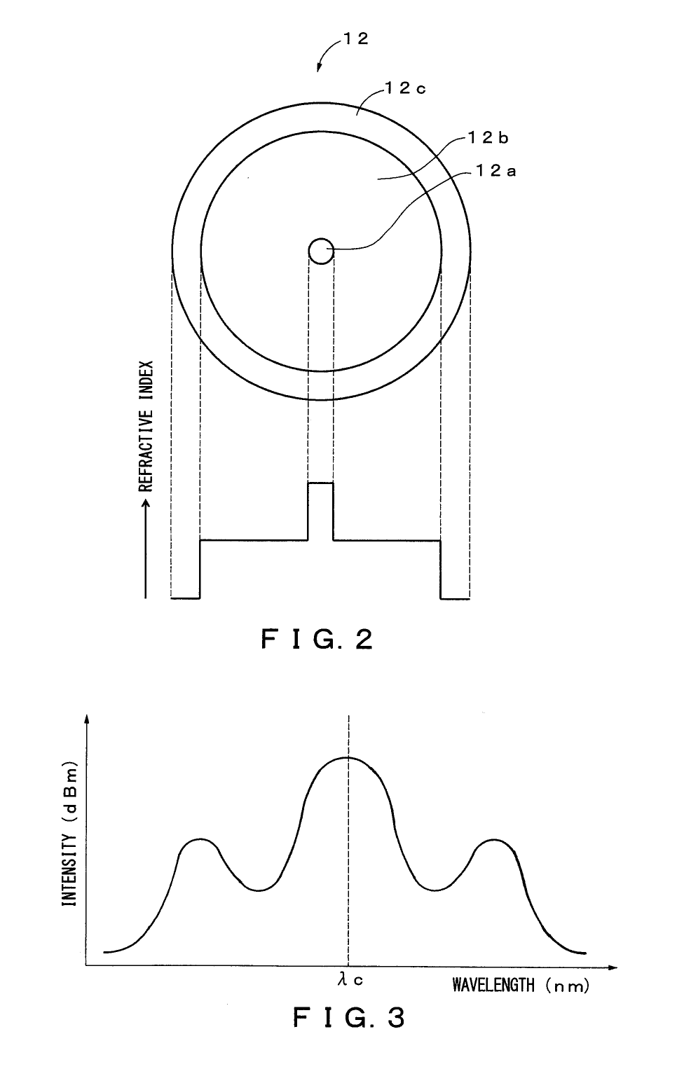

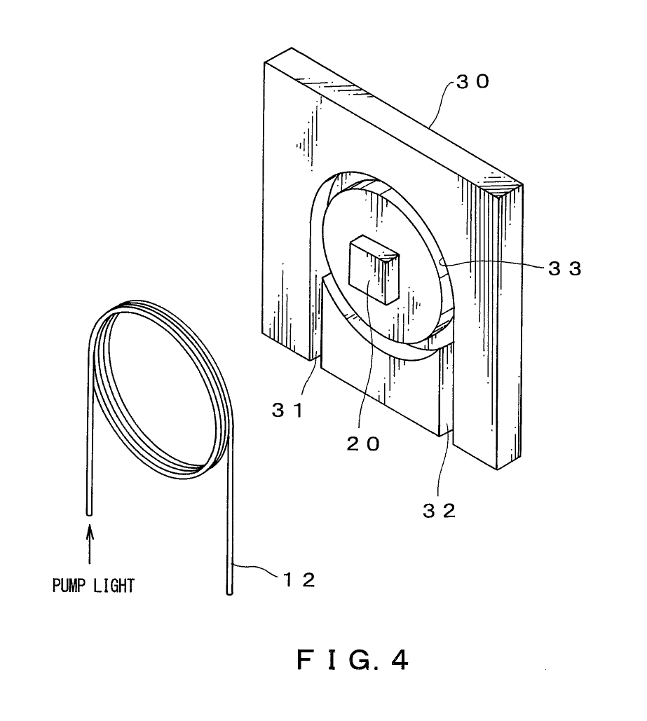

FIG. 2 is a diagram showing a cross-sectional structure of the amplification optical fiber 12 and a refractive index thereof. As shown in FIG. 2, the amplification optical fiber 12 is a double-clad optical fiber having a core portion 12a, a first cladding portion 12b and a second cladding portion 12c. As shown at a bottom part of FIG. 2, the refractive indices of the respective portions are defined in such a manner that the refractive index of the core portion 12a is the highest, and then the first cladding 12b and the second cladding 12c in this order. The optical signal propagates in the core portion 12a in a single mode and the pump light from laser diode 20 propagates in the core portion 12a and the first cladding 12b in a multimode. The core portion 12a is, for example, made of silica glass and co-doped with erbium (Er) and ytterbium (Yb). The first cladding portion 12b is, for example, made of silica glass. The second cladding portion 12c is, for example, made of resin, silica glass or the like. As will be described below, the amplification optical fiber 12 is attached to a heat sink 30 (see FIG. 4), and the laser diode 20 is thermally coupled (hereinafter, also simply referred to as “thermal coupling”) to the heat sink 30. FIG. 2 shows an example in which the first cladding portion 12b has a circular cross-section. However, it is not limited to a circular shape, and may be of a shape such as a rectangular shape, a triangular shape or a star shape.

The optical coupler 13 splits off a part of the optical signal inputted from the input port 11 and inputs the split-off part into the photodiode 18 and the remaining part into the optical isolator 15. The photodiode (PD) 18 converts the optical signal which has been split by the optical coupler 13 into a corresponding electric signal and supplies it to the control circuit 21. In the control circuit 21, the electric signal supplied from the photodiode 18 is converted into an analog signal or a corresponding digital signal to detect a light intensity of the input signal.

The optical isolator 15 has a function of transmitting the light from the optical coupler 13 and blocking the light returning from the pump light mixer 17 and the amplification optical fiber 12. The laser diode (LD) 20 is, for example, a multi-mode semiconductor laser device that generates laser light having a wavelength of a 900 nm band and serving as a pump light. FIG. 3 is a diagram showing a profile of a wavelength characteristic of laser light generated by the laser diode 20. As can be seen in FIG. 3, the laser light generated by the laser diode 20 has a characteristic that shows a predetermined spread around a center wavelength λc. This is given by way of example only and may also be other characteristics. The laser diode 20 is a semiconductor laser device of an uncooled type with no Peltier element, which serves as a cooling element.

The pump light generated by the laser diode 20 is inputted into the amplification optical fiber 12 via the pump light mixer 17 and propagates through the core portion 12a and through the first cladding portion 12b in a multimode. The optical signal outputted from the optical isolator 15 is inputted into the amplification optical fiber 12 via the pump light mixer 17 and propagates through the core portion 12a in a single mode.

The optical isolator 16 has a function of transmitting the light from the amplification optical fiber 12 and blocking the light returning from the optical coupler 14. The optical coupler 14 splits a part of the optical signal outputted from the optical isolator 16 and inputs the split-off part into the photodiode 19, and outputs the remaining part from the output port 24. The output port 24 is, for example, an optical connector or the like and externally outputs the amplified optical signal. The photodiode (PD) 19 converts the optical signal which has been branched off by the optical coupler 14 into a corresponding electric signal and supplies it to the control circuit 21. The control circuit 21 converts the electric signal supplied from the photodiode 19 into an analog signal or a corresponding digital signal and detects a light intensity of the input signal.

The control circuit 21 includes, for example, a CPU (Central Processing Unit), a ROM (Read Only Memory), a RAM (Random Access Memory), an A/D (Analog to Digital) conversion circuit and a D/A (Digital to Analog) conversion circuit, and, the CPU performs an arithmetic process using the RAM as a work area in accordance with a program stored in the ROM and controls an operating current of the laser diode 20 based on the signals supplied from the photodiodes 18 and 19 to perform an ALC (Automatic Output Power Level Control) such that an intensity of an optical signal outputted from the optical amplifying apparatus 10 becomes constant or an AGC (Automatic Gain Control) such that the gain becomes constant. Based on a temperature of the laser diode 20 detected by the thermistor 22, the cooling section 23 is driven in such a manner that the temperature of the laser diode 20 is controlled to come to a desired temperature. The control circuit 21 may be, for example, a DSP (Digital Signal Processor) or the like.

The thermistor (TH) 22 is thermally coupled to the laser diode 20, detects the temperature of the laser diode 20, and supplies the result of detection to the control circuit 21. The cooling section (FAN) 23 serving as the temperature adjustment section includes, for example, a compact motor and a blast fan, and is driven under the control of the control circuit 21 to control the laser diode 20 to come to a desired temperature by blowing air on the heat sink 30. The cooling section 23 may be controlled by, for example, simply performing an ON/OFF control depending on the temperature, or by controlling a number of rotations depending on the temperature.

FIG. 4 is a diagram showing an exemplary configuration of the heat sink 30. The heat sink 30 is, for example, made of a metal plate having a good thermal conductivity such as aluminum or copper. The metal plate has, in one of its faces (a near-side face in FIG. 4), a straight groove portion 31 in which one of the straight portions of the amplification optical fiber 12 wound in a coil is to be accommodated, a straight groove portion 32 in which the other straight portion is to be accommodated, and a circular groove portion 33 in which a wound-up circular portion is to be accommodated. Since an internal radius of a portion of the amplification optical fiber 12 wound in a coil and a radius of an inner side surface of the circular groove portion 33 are substantially the same, when the amplification optical fiber 12 is accommodated in the circle groove 33 of the heat sink 30, an inner side of the wound-up portion of the amplification optical fiber 12 and an inner side surface of the circular groove portion 33 come into contact and a thermal coupling is established therebetween. In order to improve thermal conductivity, widths of the straight groove portions 31, 32 and the circular groove portion 33 may be substantially the same as a diameter of the amplification optical fiber 12 to make both side-surfaces of the groove come into contact with both sides of the amplified optical fiber 12, respectively. Further, for example, a thermally-conductive silicon may be interposed between the two to further improve the thermal conductivity.

The laser diode 20 is disposed substantially at a center of a top portion of a raised portion surrounded by the circular groove portion 33. Similarly to the aforementioned case, in order to improve thermal conductivity, a thermally-conductive silicon may be interposed between the two. Also, although not illustrated in FIG. 4, the thermistor 22 shown in FIG. 1 is thermally coupled to the laser diode 20 in such a manner that the temperature of the laser diode 20 is detectable. Similarly, although not illustrated in FIG. 4, the cooling section 23 shown in FIG. 1 is, for example, disposed at a position at which cooling of the laser diode 20 can be performed. The cooling section 23 may be provided at a back side (a far side in FIG. 4) of the heat sink 30 instead of a front side (a near side in FIG. 4) of the heat sink 30. Alternatively, a plurality of fins (Fin) may be provided on a backside of the heat sink 30 and the cooling section 23 may perform the cooling on the fin.

(B) Operation of Embodiment

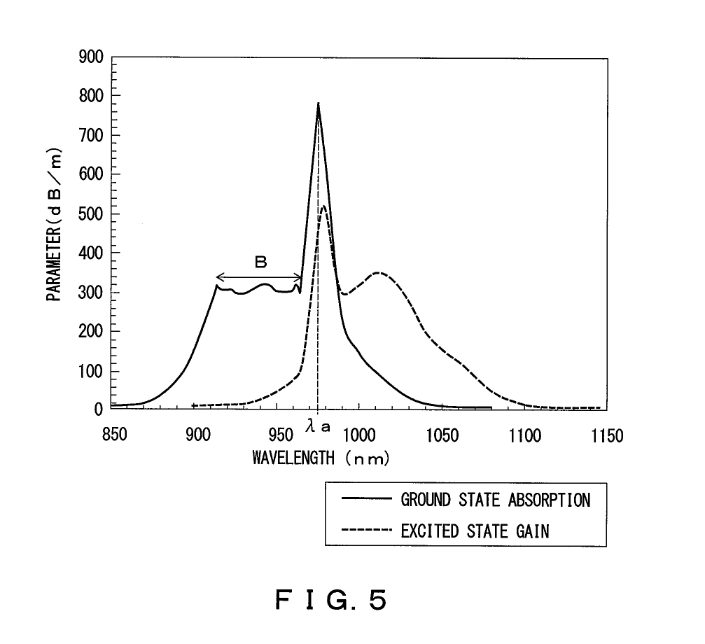

An outline of an operation of the present embodiment will now be described, and thereafter, the operation will be described in detail. In this embodiment, a double-clad amplification optical fiber 12 co-doped with erbium and ytterbium is used. FIG. 5 is a diagram showing changes in a ground state absorption (Ground-State Absorption) and an excited state gain (Excited-State Gain) of such an amplification optical fiber 12 with respect to the wavelength. The curve indicating the ground state absorption has a flat band B around 910-960 nm and has a peak at around 975 nm. In the uncooled multi-mode laser diode 20, the wavelength of the generated laser light shifts toward the long-wavelength side depending on an increase in the temperature. For example, when there is a temperature increase of 75° C., the wavelength shifts toward the long-wavelength side by 22.5 nm. Therefore, generally, in order to prevent changes in an absorption characteristic due to a temperature change in the laser diode 20, the center wavelength λc of the pump light generated by the laser diode 20 is generally designed to be within the flat band B shown in FIG. 5.

On the other hand, herein, the amplification optical fiber 12 that generates heat during operation and the laser diode 20 are thermally coupled by the heat sink 30, which is a thermal conductive medium, and heat generated by the amplification optical fiber 12 is positively used to increase the temperature of the laser diode 20. The characteristics of the laser diode 20 and the characteristics of the amplification optical fiber 12 are determined in such a manner that, when a thermally steady state is reached (heat generated in the amplification optical fiber 12 and heat emitted from the heat sink 30 are balanced and a temperature of the laser diode 20 has become constant), the center wavelength λc of the pump light generated by the laser diode 20 substantially matches a peak wavelength λa (975 nm in the example of FIG. 5) for the ground state absorption of the amplification optical fiber 12. Alternatively, the temperature of the laser diode 20 is controlled in such a manner that the center wavelength λc and the peak wavelength λa substantially match. With such a method, since an absorption factor of the pump light can be increased in comparison with the case in which the flat band B is used as in the related art, even in a case where the length of the amplification optical fiber 12 is made shorter for the purpose of improving an analog characteristic, an intensity of the residual pump light can be decreased. Further, by using the amplification optical fiber 12 in a band having a higher absorption factor, a conversion efficiency (a ratio of the signal gain against the pump light input power) can be improved. Even if the temperature has changed and the wavelength of the pump light generated by the laser diode 20 has changed, as long as it is within a range in which the absorptance is higher than band B, the residual pump light can be decreased and a conversion efficiency can be improved as compared to the related art.

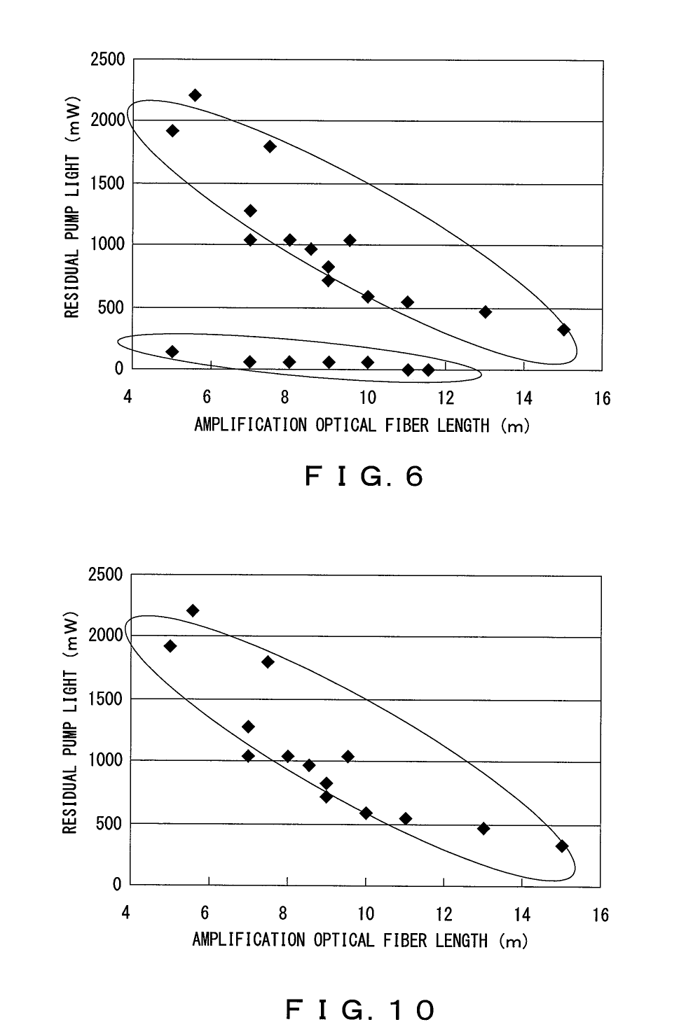

FIG. 6 is a diagram showing a relationship between the residual pump light and the length of the amplification optical fiber 12 for the related art and the present embodiment. Dots shown in an upper ellipse in FIG. 6 indicate a relationship between the residual pump light and the fiber length in the related art. Dots shown in a lower ellipse in FIG. 6 indicate a relationship between the residual pump light and the fiber length according to the present embodiment. By comparing these, it can be seen that in the case of the invention, even if the length of the amplification optical fiber 12 is decreased, the residual pump light does not increase as in the case of the related art.

Thus, herein, since the laser diode 20 and the amplification optical fiber 12 are thermally coupled via the heat sink 30, and the center wavelength λc of the pump light generated by the laser diode 20 when these reach a thermally steady state is configured to substantially match the peak wavelength λa at which the ground state absorption of the amplification optical fiber 12 has a peak, an increase in the residual pump light can be suppressed while improving an analog characteristic. Also, a conversion efficiency can be improved by using a peak position at which the absorption characteristic of the amplification optical fiber 12 has a peak.

Also, since a laser diode of an uncooled type can be used as the laser diode 20, an electric power to be consumed by a Peltier element (an electric power of approximately double the electric power necessary for driving the laser diode 20) becomes unnecessary, and a power consumption of the optical amplifying apparatus 10 can be decreased to one-third or less. Further, by omitting a Peltier element serving as a radiator, the size of the overall apparatus can be reduced. Further, by using the double-clad amplification optical fiber 12 co-doped with erbium and ytterbium, an increased gain can be obtained easily.

Next, a detailed operation of the present embodiment will be described.

In the present embodiment, the case of amplifying an optical signal having a wavelength of 1550 nm obtained by modulating laser light with an AM-VSB signal having 40 sinusoidal carriers of a frequency within a range of 91.25-343.25 MHz. When the optical signal is inputted from the input port 11, the optical coupler 13 splits it and a part of the signal is inputted into the photodiode 18. Specifically, in a case where the optical coupler 13 is a 20 dB coupler (in a case where the split ratio is 1/100), 1/100 of the optical signal is inputted into the photodiode 18 and the remaining part is inputted into the optical isolator 15.

The photodiode 18 converts the inputted optical signal into an electric signal and supplies it to the control circuit 21. After having converted the inputted electric signal into an analog signal or a corresponding digital signal, the control circuit 21 calculates an intensity of the optical signal inputted from the input port 11 based on the obtained data and a split ratio of the optical coupler 13.

The optical signal which has passed through the optical isolator 15 is guided to the pump light mixer 17. The optical signal which has passed through the optical isolator 15 is inputted to the core portion 12a of the amplification optical fiber 12 via the pump light mixer 17 and propagates in the core portion 12a in a single mode. On the other hand, the pump light generated by the laser diode 20 is inputted to the core portion 12a and the first cladding portion 12b of the amplification optical fiber 12 via the pump light mixer 17, and propagates inside the core portion 12a and the first cladding portion 12b in the multi-mode. The pump light is absorbed by an ytterbium ion (Yb³⁺) in the core portion 12a while propagating through the amplification optical fiber 12, and the ytterbium ion indirectly excites an erbium ion (Er^{3═}). The optical signal that propagates through the core portion 12a is amplified by a stimulated emission from the excited erbium ion.

The amplification optical fiber 12 generates heat during an amplification operation. For example, when the amplification optical fiber 12 having a length of 8m is pumped with the laser diode 20 having a power of 8W, the ambient temperature increases to nearly 60° C. In the present embodiment, since the amplification optical fiber 12 is attached to the heat sink 30 shown in FIG. 4, heat generated by the amplification optical fiber 12 is transferred through the heat sink 30 serving as the thermally conductive medium. Since the laser diode 20 is disposed at the center of the heat sink 30 and the laser diode 20 is thermally coupled to the heat sink 30, the temperature of the laser diode 20 increases due to the heat transferred from the amplification optical fiber 12. The heat transferred through the heat sink 30 is emitted into the surroundings by thermal radiation. The thermistor 22 is thermally coupled to the laser diode 20 and detects a device temperature. The detection result of the temperature of the laser diode 20 detected in this manner is supplied to the control circuit 21. The control circuit 21 determines whether the temperature of the laser diode 20 is equal to a preset and stored temperature Tc, e.g., 50° C. (the temperature at which λc and λa substantially match), and in a case the detected temperature is higher than temperature Tc, operates the cooling section 23 and if this is not the case, does not operate the cooling section 23. With such a control, since the temperature of the laser diode 20 is controlled to come to temperature Tc, the device temperature of the laser diode 20 becomes equal to temperature Tc when the system including the cooling section 23 has reached a thermally steady state.

When the temperature of the laser diode 20 increases, the wavelength of the pump light generated by the laser diode 20 shifts toward the long-wavelength side. Here, the center wavelength λc (see FIG. 3) of the pump light generated when the temperature of the laser diode 20 is equal to Tc is set to substantially match with the peak wavelength λa (see FIG. 5) of the ground state absorption of the amplification optical fiber 12. As a result, the pump light generated from the laser diode 20 is absorbed by the amplification optical fiber 12 with a high percentage, and used in the amplification of the optical signal. Therefore, even in a case where the length of amplification optical fiber 12 is decreased for the purpose of improving an analog characteristic, an intensity of the residual pump light can be decreased. As has been described above, FIG. 6 is a plot showing the relationship between the length of the amplification optical fiber 12 and the intensity of the residual pump light. The dots surrounded by the upper ellipse in FIG. 6 show the relationship between the length of the amplification optical fiber 12 and the intensity of the residual pump light of the related art, and it can be seen that the intensity of the residual pump light significantly increases as the length of the amplification optical fiber 12 becomes shorter. On the other hand, the dots surrounded by the lower ellipse in FIG. 6 shows the relationship between the length of the amplification optical fiber 12 and the intensity of the residual pump light according to the present embodiment, and it can be seen that an increase in the intensity of the pump light is very small even if the length of the amplification optical fiber 12 is shortened. Considering a proof stress of an optical passive component, it is desirable that the power of the residual pump light outputted from the amplification optical fiber 12 is set at 500 mW or below. It is to be noted that 500 mW is a value generally used as a high-power proof stress value of the optical passive component, and that the optical passive component can be prevented from being damaged and have a longer life with the residual pump light being set at 500 mW or below. Instead of setting at 500 mW or below, for example, it may be set to be less than or equal to the power of the optical signal outputted from the amplification optical fiber 12. This is because, as long as it is lower than the power of the optical signal, the optical passive component will not be damaged.

The optical signal amplified by the amplification optical fiber 12 is inputted into the optical coupler 14 via the optical isolator 16. The optical coupler 14 splits a part of the inputted optical signal and the split-off part is inputted to the photodiode 19. Specifically, in a case where the optical coupler 14 is a 20 dB coupler (in a case where the split ratio is 1/100), 1/100 of the optical signal is inputted into the photodiode 19, and the remaining part is outputted from the output port 24.

The photodiode 19 converts an inputted optical signal into an electric signal and supplies it to the control circuit 21. After having converted the inputted electric signal into an analog signal or a corresponding digital signal, the control circuit 21 calculates an intensity of the amplified optical signal based on the obtained data and the split ratio of the optical coupler 14. Then, the control circuit 21 determines a gain of the optical amplifying apparatus 10 based on the intensity of the input light calculated by the aforementioned process and the intensity of the output light. Then, based on the obtained gain, an automatic gain control (AGC) is performed which is a control for making the gain constant. Alternatively, an automatic output power level control (ALC) is performed in which only the intensity of the output light is detected and an output intensity is kept constant. Other than this, the control may be performed based on an automatic current control (ACC) which is a control for making the pump current constant or an automatic pump power control (APC) in which is a control for making the pump power constant.

As has been described above, according to the embodiment of the invention, the laser diode 20 and the amplification optical fiber 12 are thermally coupled via the heat sink 30 serving as a thermal conductive medium and the heat generated by the amplification optical fiber 12 is transferred to the laser diode 20. The center wavelength λc of the pump light generated by the laser diode 20 when a thermally steady state is reached substantially matches the peak wavelength λa at which the absorptance of the pump light of amplification optical fiber 12 has a peak. Therefore, the intensity of the residual pump light can be prevented from increasing even in a case where the length of the amplification optical fiber 12 is decreased for the purpose of improving the analog characteristic.

In the present embodiment, the amplification optical fiber 12 and the laser diode 20 are thermally coupled via the heat sink 30. Since the heat sink 30 is generally made of metal such as aluminum having a high thermal conductivity, heat generated by the amplification optical fiber 12 can be rapidly transferred to the laser diode 20 and the temperature can be controlled without delay.

In the present embodiment, since the thermistor 22 is thermally coupled to the laser diode 20 and the cooling section 23 is controlled based on a temperature detected by the thermistor 22, the laser diode 20 can be always kept at a constant temperature. With such a control, the intensity of the residual pump light can be controlled to be constant at a lower level without being influenced by an environmental temperature. Also, a conversion efficiency of the amplification optical fiber 12 can be maintained at a high level.

According to the present embodiment, an uncooled-type laser diode is used as the laser diode 20. Therefore, since an electric power to be consumed by the Peltier element becomes unnecessary, the power consumption of the optical amplifying apparatus 10 can be decreased to about one-third, and also, since the Peltier element serving as the radiator is eliminated, an overall apparatus of the system can be reduced. In the present embodiment, the cooling section 23 is used and the power consumption of the cooling section 23 is smaller than that of the Peltier element. Therefore, even in a case where the cooling section 23 is operated frequently (or continuously), the power consumption can be reduced as compared to the Peltier element.

In the present embodiment, as shown in FIG. 4, the amplification optical fiber 12 is wound in such a manner that an end portion of the amplification optical fiber 12 whereto an pump light is inputted is situated on a near side. The amplification optical fiber 12 has a distribution in which a temperature of the end portion whereto the pump light is inputted is high and the temperature decreases as the distance from the input end becomes greater. Therefore, with the end portion of the amplification optical fiber 12 having a high temperature being disposed at a side nearer to the laser diode 20, the heat of the amplification optical fiber 12 can be efficiently transferred to the laser diode 20.

FIG. 7 is a schematic configuration diagram illustrating a case where the optical amplifying apparatus of the present embodiment is employed in an optical transmission system 50. In an example shown in FIG. 7, the optical transmission system 50 has an optical signal transmitting apparatus 60, a transmitting-side optical transmission path 70, the optical amplifying apparatus 10 of the present embodiment, a receiving-side optical transmission path 80 and an optical signal receiving apparatus 90. In this example, an optical signal transmitted from the optical signal transmitting apparatus 60 propagates through the transmitting-side optical transmission path 70 and reaches the optical amplifying apparatus 10. The optical signal is amplified in the optical amplifying apparatus 10, as has been described above, and then propagates through the receiving-side optical transmission path 80 and arrive at the optical signal receiving apparatus 90 in which the signal is demodulated. Since the optical amplifying apparatus 10 of the present embodiment has a good analog characteristic and a low power consumption, the optical transmission system 50 employing such an optical amplifying apparatus 10 can achieve an improved communication quality for the entire system, a decrease in the power consumption and a saving of expenses required for the maintenance of the system.

(C) Variant Embodiments

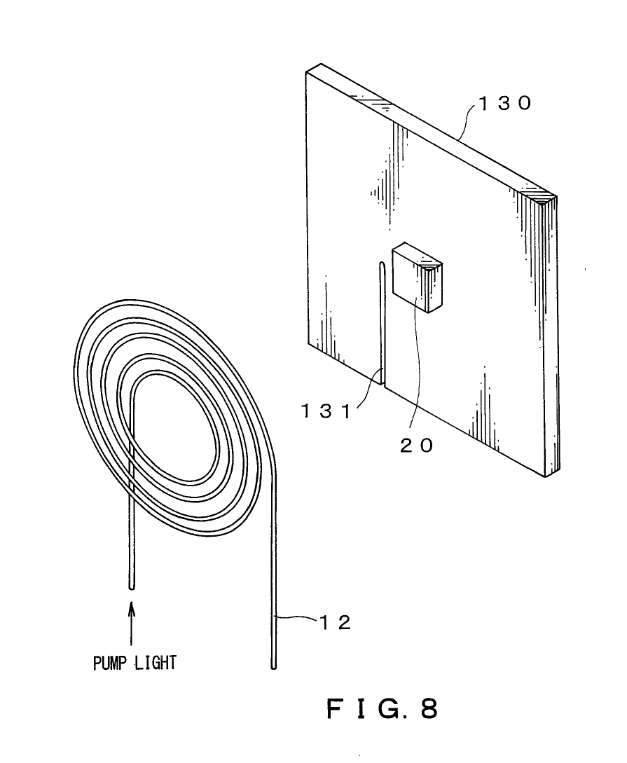

In the above-mentioned embodiment, the heat sink 30 as shown in FIG. 4 was used, but other configurations, such as a configuration shown in FIG. 8, are also conceivable. In the example of FIG. 8, a heat sink 130 is, for example, made from a plate of a thermally-conductive metal such as aluminum or copper. In one of the faces of the metal plate, a straight groove portion 131 is formed in which one end of the amplification optical fiber 12 is to be embedded, and a straight portion at an end portion of the amplification optical fiber 12 whereto a pump light is inputted is embedded in the straight groove portion 131. The amplification optical fiber 12 extending upward from the straight groove portion 131 is wound from an inner side towards an outer side to form a spiral such that its radius gradually increases, and the other end portion extends outward from the heat sink 130 in the same direction as the straight groove portion 131. Since the straight portion of the amplification optical fiber 12 whereto the pump light is inputted is embedded in the straight groove 131 and its surface is substantially at the same level as the surface of the heat sink 130, the spiral portion can be disposed without being bent for avoiding the straight portion. The amplification optical fiber 12 is, for example, attached to the heat sink 130 by an adhesive or the like. Near the center of the spiral portion of the amplification optical fiber 12, the laser diode 20 is disposed in such a manner that it is thermally coupled to the heat sink 130 via, for example, thermally conductive silicon for improving thermal conductivity. Similarly to the aforementioned case, the laser diode 20 is thermally coupled to the thermistor 22 shown in FIG. 1 and the temperature of the laser diode 20 is detectable. Also, for example, the cooling section 23 shown in FIG. 1 is disposed at a location where the cooling of the laser diode 20 can be performed. It is also possible to provide the cooling section 23 on a back side of the heat sink 130 instead of a front side, and alternatively, a plurality of fins may be provided on the back side of the heat sink 130 and the cooling may be performed by cooling the fins with the cooling section 23.

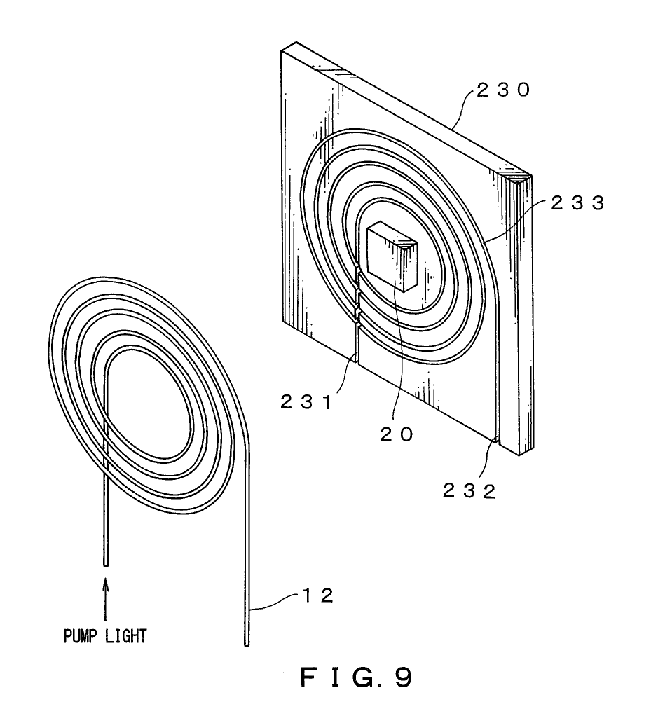

FIG. 9 is a diagram showing another embodiment of the heat sink. In the exemplary configuration of FIG. 8, only a part of the amplification optical fiber 12 was embedded in the heat sink 130, whereas in the configuration of FIG. 9, the entire amplification optical fiber 12 is embedded in a heat sink 230. That is to say, in this example, the heat sink 230 is provided with a straight groove portion 231 in which one of the straight portions of the amplification optical fiber 12 is to be accommodated, a straight groove portion 232 in which the other straight portion is to be accommodated, and a spiral groove portion 233 in which a portion wound in a spiral shape is to be accommodated that are formed therein. The straight groove 231 in which one end of the amplification optical fiber 12 is embedded has a depth deeper than that of other portions by the diameter of the fiber. In this manner, with a configuration in which the amplification optical fiber 12 is embedded in the heat sink 230, a contact area between the amplification optical fiber 12 and the heat sink can be increased and a thermal conductivity can be improved. Although not shown in FIG. 9, after having embedded the amplification optical fiber 12, a surface of the heat sink 230 may be sealed with, for example, a sheet of resin having an opening corresponding to the laser diode 20, to thereby prevent the amplification optical fiber 12 from being damaged. Also, by using a thermally conductive resin, the thermal coupling between the amplification optical fiber 12 and the heat sink 230 can be further improved.

In the examples of FIGS. 8 and 9, since the amplification optical fiber 12 is wound spirally in such a manner that the end portion thereof whereto the pump light is inputted is at an inner side, heat can be efficiently transferred to the laser diode 20 by arranging a portion of the amplification optical fiber 12 where the temperature becomes high in the vicinity of the laser diode 20. In a case where the laser diode 20 and the amplification optical fiber 12 are thermally coupled via the heat sink, the shape of the heat sink is not limited to those of the aforementioned embodiments. For example, each groove portion for accommodating the fiber is not necessarily required.

In the aforementioned embodiments, although the amplification optical fiber 12 and the laser diode 20 were thermally coupled, other configurations, such as a configuration in which a passive optical component (e.g., the optical isolator 16 or the optical coupler 14) located on an output end side of the amplification optical fiber 12 and the laser diode 20 are thermally coupled, are also conceivable. This is because the passive optical component located on the output end side also generates heat. A manner of providing thermal coupling includes, as has been described above, a thermal coupling via a heat sink, or alternatively, thermally coupling the laser diode 20 and the passive optical component directly. Further, the passive optical component may be placed near the laser diode 20 of the heat sink 30, 130 and 230 shown in FIGS. 4, 8, and 9, respectively, and use heat from both the amplification optical fiber 12 and the passive optical component. Since an amount of heat generated by the amplification optical fiber 12 varies due to variation in absorptance depending on a shift in the wavelength outputted from the laser diode 20, whereas the amount of heat generated by the passive optical component disposed on an output side is stable with respect to the shift in the wavelength, a reduction control of the residual pump light can be performed in a stable manner by thermally coupling the passive optical component and the laser diode 20.

In the aforementioned embodiment, the thermistor 22 and the cooling section 23 are provided and a temperature control is performed using the thermistor 22 and the cooling section 23. However, for example, in a case where the temperature of the laser diode 20 can be maintained at a desired temperature without performing a temperature control, these need not be provided.

In the aforementioned embodiment, a case in which cooling is performed by making use of the cooling section 23 serving as a temperature adjustment portion has been described. However, it is possible to perform heating using a heating section that serves as the temperature adjustment section. Specifically, it is possible to provide a heater having a heating function as a temperature adjustment section, and to control the temperature of the laser diode 20 to approach temperature Tc by heating with the heater in a case where the environment temperature is low and an excitation wavelength becomes short. The controlling method may be a method in which an amount of heat generated by the heater is controlled in accordance with the temperature detected by the thermistor 22. Alternatively, since the temperature control has a large time constant (the change is slow), it is possible to perform a switching control by turning ON/OFF the heater. Of course, in the case of cooling, the fan may be controlled by controlling the number of rotations or by performing an ON/OFF control.

Further, immediately after having started up the optical amplifying apparatus 10, since the temperature of the laser diode 20 is low and the excitation wavelength is short, the residual pump light level may be high until a steady state is reached. Therefore, immediately after the start-up of the optical amplifying apparatus 10, the laser diode 20 may be heated using a heater to come to a steady state and the heating by the heater may be weakened as it changes into the steady state. With such a method, it is possible to prevent the shortening of life of the optical device or the damaging of the optical device due to the residual pump light.

The control may be a combination of the cooling by the cooling section 23 and the heating by the heater. With such a combined control, even in a case where there is a large fluctuation in the ambient temperature, the temperature of the laser diode 20 can be kept constant.

In the aforementioned embodiments, for the purpose of preventing the residual pump light generated immediately after the start-up of the optical amplifying apparatus 10, configurations in which the heating is performed temporarily with a heater have been described. However, a configuration for achieving such a purpose is not limited thereto. For example, a residual pump light removing section may be provided at a stage downstream of the amplification optical fiber 12, and a residual pump light that occurs in a transient state during the start-up may be converted to heat and removed. The residual pump light removing section may be, for example, obtained by providing, at an outside of a cladding of the single-mode fiber, which is situated on a downstream side and whereto a multi-mode light emitted from a cladding of the amplification optical fiber 12 is incident, a member that has substantially the same or slightly greater refractive index with respect to that of the cladding of the single-mode fiber. The residual pump light removing section can remove the residual pump light by converting the residual pump light into heat by making a thermal contact with a separately provided heat dissipating member.

In the aforementioned embodiment, a heat sink was used as a thermally-conductive medium, but a medium other than the heat sink may be used as the thermally-conductive medium. Specifically, for example, a metal housing that houses the optical amplifying apparatus 10 may be used as a thermally-conductive medium. Also, the thermally-conductive medium is not limited to metal, and, for example, air may be used as a heat conduction medium. That is to say, the laser diode 20 may simply be disposed in the vicinity of the amplification optical fiber 12 or the passive optical component. It is to be noted that other than these, liquid such as water or an organic solvent or the like, or resin etc., may be used as the heat conduction medium.

In the aforementioned embodiment, an end portion of the amplification optical fiber 12 whereto a pump light is inputted is disposed near the laser diode 20, whereas, in a case where the temperature of the laser diode 20 becomes greater than or equal to a desired temperature, the end portion whereto the pump light is inputted may be disposed at a position distant from the laser diode 20. The position at which the laser diode 20 is attached is not limited to the positions in FIGS. 4, 8 and 9, but may be, for example, attached to one of the four corners of the heat sink or may be attached to a reverse face of the heat sink.

In the aforementioned embodiment, although the relationship between the output control (e.g., ALC, etc.) and the temperature control has not been described, a response speed of control is fast for an output control and a response speed is slower for a temperature control as compared to the output control. Accordingly, for example, in order to control the output to be constant, by performing a control based on an output control in a short term and performing a control by a temperature control to bring the temperature of the laser diode 20 to a desired temperature in a long term, the analog characteristic can be improved while decreasing the intensity of the residual pump light.

In the aforementioned embodiment, the pump light generated by the laser diode 20 has been described as having a wavelength characteristic shown in FIG. 3. However, in a case where the pump light shows a characteristic which is different from the characteristic shown in FIG. 3 (e.g., in a case where a significant peak wavelength does not exist), an absorptance by the amplification optical fiber 12 may be set to become the highest when the wavelength is shifted by a temperature rise. That is to say, during a temperature rise, an overlapping area of the wavelength characteristic shown in FIG. 3 and the absorption property shown in FIG. 5 may be set to become the largest.

In the above-mentioned embodiments, a forward excitation method is employed as an excitation method. However, for example, a backward excitation method or a bidirectional excitation method may be employed. The backward excitation method has a lower noise characteristic as compared to the forward excitation method but can achieve a higher power. The bidirectional excitation method enables an amplification in which characteristics of both the forward excitation method and the backward excitation method are combined.

In the aforementioned embodiment, the optical amplifying apparatus 10 includes only a booster amplifier, but, for example, in order to improve NF which is a noise factor, after having performed amplification by a preamplifier provided at a stage upstream of the booster amplifier, the booster amplifier may perform further amplification.

Also, in each of the aforementioned embodiments, the cases in which a core portion 12a co-doped with erbium and ytterbium has been used in the explanation, but a rare-earth element such as thulium (Tm: Thulium), neodymium (Nd: Neodymium), praseodymium (Pr: Praseodymium) or other substances having a similar amplification function as the rare-earth element may be added. In such a case, the amplification band is different from each of the aforementioned embodiments, but an effect similar to that of the present invention can be obtained.

What is claimed is:

1. An optical amplifying apparatus that amplifies an optical signal, comprising:
an input section whereto the optical signal is inputted;
a laser light source that generates laser light, the laser light source including an uncooled semiconductor laser device;
an optical fiber that amplifies the optical signal by a stimulated emission based on the laser light from the laser light source;
an output section that outputs the optical signal amplified by the optical fiber; and
a passive optical component disposed between the optical fiber and the output section,
the laser light source being thermally coupled to the optical fiber and/or the passive optical component via a thermally conductive medium,
an oscillating wavelength of the laser light source being varied by increasing a temperature of the laser light source with heat generated by the optical fiber and/or the passive optical component.

2. The optical amplifying apparatus according to claim 1, wherein the heat generated by the optical fiber and/or the passive optical component is transferred to the laser light source, and a wavelength band of laser light generated by the laser light source when a thermally steady state is reached is set to substantially match a wavelength at which an absorptance of the optical fiber is high.

3. The optical amplifying apparatus according to claim 1, wherein the thermally conductive medium is a heat sink that dissipates heat generated by the optical fiber and/or the passive optical component, and the laser light source and the optical fiber and/or the passive optical component are thermally coupled by disposing the laser light source on the heat sink.

4. The optical amplifying apparatus according to claim 3, further comprising:
a temperature detecting section that detects a temperature of the laser light source and thermally coupled to the laser light source; and
a temperature adjusting section that adjusts a temperature of a system including the laser light source based on a temperature detection result from the temperature detecting section in such a manner that a wavelength band of laser light generated by the laser light source substantially matches a wavelength band in which an absorptance of the optical fiber is high,
the temperature adjusting section including a cooling section that cools the heat sink, an oscillating wavelength of the laser light source being controlled by increasing a temperature of the laser light source with heat generated by the optical fiber and/or the passive optical component by controlling a power of the laser light source and cooling the laser light source by the cooling section.

5. The optical amplifying apparatus according to claim 1, wherein a power of a residual pump light outputted from the optical fiber being set at less than or equal to 500 mW.

6. The optical amplifying apparatus according to claim 1, wherein the optical fiber is a double-clad optical fiber and the laser light source is composed of a multimode semiconductor laser device.

7. An optical transmission system comprising:
an optical transmitting apparatus that transmits an optical signal;
the optical amplifying apparatus according to claim 1; and
an optical receiving apparatus that receives the optical signal amplified by the optical amplifying apparatus.
